(19) United States
(12) Patent Application Publication
(10) Pub. No.: US 2025/0167016 A1
(43) Pub. Date: May 22, 2025

(54) RESIN SEALING DEVICE AND RESIN SEALING METHOD

(71) Applicant: APIC YAMADA CORPORATION, Nagano (JP)

(72) Inventors: Shusaku Tagami, Nagano (JP); Makoto Yanagisawa, Nagano (JP)

(73) Assignee: APIC YAMADA CORPORATION, Nagano (JP)

(21) Appl. No.: 18/839,727

(22) PCT Filed: Jan. 12, 2023
(86) PCT No.: PCT/JP2023/000537

§ 371 Date: Aug. 20, 2024

(30) Foreign Application Priority Data
May 31, 2022 (JP) 2022-089090

(51) Int. Cl. H01L 21/67; H01L 21/677

(52) U.S. Cl. CPC H01L 21/67126; H01L 21/67253; H01L 21/67736

(57) ABSTRACT

A resin sealing device resin-seals an electronic component of a workpiece including a base material and the electronic component. This resin sealing device includes: a resin sealing mold which resin-seals an electronic component by molding a resin material onto a workpiece; a conveyance line for conveying the workpiece to the resin sealing mold; a workpiece accommodation part capable of accommodating at least one workpiece; a workpiece support part which is provided between the workpiece accommodation part and the conveyance line and supports the workpiece; a pickup device which holds the workpiece supplied onto the workpiece support part from the workpiece accommodation part, and conveys the workpiece to the conveyance line; and a measurement part which is provided in at least one among the workpiece accommodation part, the workpiece support part, and the pickup device, and measures the weight of the workpiece.

### TECHNICAL FIELD

The present invention relates to a resin sealing device and a resin sealing method.

### RELATED ART

As an example of a resin sealing device which melts resin onto a workpiece including a base material and an electronic component to resin-seal the electronic component, a resin sealing device which molds resin onto the workpiece is known. When sealing electronic component with resin, the resin amount is calculated and supplied on a workpiece basis, whereby uniform resin sealing without waste of sealing resin can be ensured.

In Patent Document 1, a technique is disclosed in which the amount of resin to be dispensed onto a workpiece is calculated based on appearance information of each workpiece in advance, and the resin onto the workpiece to perform resin sealing. Specifically, defect information of the workpiece supplied onto the support rail is acquired by a camera, and based on the information, a target resin dispense weight of the resin to be dispensed onto the workpiece is calculated, and the resin is dispensed onto the workpiece by a dispenser. Moreover, the dispensed resin weight is calculated from the weight difference of the weights of the workpiece measured before and after the resin is dispensed, and information acquired by comparing the target resin dispense weight with the dispensed resin weight is used to correct the dispensing of resin for the next workpiece.

### PRIOR-ART DOCUMENT

### Patent Document

[Patent Document 1] Patent Document 1: Japanese Patent Laid-Open No. 2003-165133

### SUMMARY OF INVENTION

### Problems to be Solved by the Invention

However, in the configuration disclosed in Patent Document 1, the amount of resin to be dispensed onto the workpiece is calculated and supplied based on appearance information of the workpiece, there is variation in thickness between molded products. Moreover, in Patent Document 1, when measuring the weight of the workpiece in the process of reducing the thickness variation between molded products, the workpiece on the support rail is moved to a weight measuring device, the weight of the workpiece is measured, and then the workpiece is returned to the support rail again. Since such a step must be performed at least twice before and after the resin is dispensed onto the workpiece, the convey time of the workpiece becomes long.

The present invention is made in consideration of the above circumstances, and an object of the present invention is to provide a resin sealing technique that can shorten the convey time of a workpiece.

### Means for Solving the Problems

A resin sealing device according to one aspect of the present invention resin-seals an electronic component of a workpiece including a base material and the electronic component. The resin sealing device includes: a resin sealing mold which resin-seals the electronic component by molding a resin material onto the workpiece; a conveyance line for conveying the workpiece to the resin sealing mold; a workpiece accommodation part capable of accommodating at least one of the workpieces; a workpiece support part which is provided between the workpiece accommodation part and the conveyance line and supports the workpiece; a pickup device which holds the workpiece supplied onto the workpiece support part from the workpiece accommodation part, and conveys the workpiece to the conveyance line; and a measurement part which is provided in at least one among the workpiece accommodation part, the workpiece support part, and the pickup device, and measures a weight of the workpiece.

According to this aspect, by providing the measurement part in at least one among the workpiece accommodation part, the workpiece support part, and the pickup device, the weight of the workpiece may be measured from when the workpiece is supplied to when it is conveyed to the conveyance line. As a result, since the weight of the workpiece may be measured during the step from when the workpiece is supplied to when it is conveyed to the conveyance line, there is no need to set up a separate step for measuring the weight of the workpiece, which shortens the convey time of the workpiece. For example, when some of the multiple chips mounted on the workpiece are defective, there is no need to provide a separate step for accurately measuring and changing the resin amount of the resin material to be supplied to the workpiece based on the degree of defect, and by measuring the weight of the workpiece and supplying the resin material to a workpiece W based on this, the convey time of the workpiece can be shortened.

In the above aspect, the measurement part is provided in the workpiece accommodation part, and further provided is a resin amount calculation part which calculates a resin amount of the resin material to be supplied to the workpiece on a workpiece basis, based on the weight of the workpiece acquired by the measurement part.

In the above aspect, the measurement part is provided in the workpiece accommodation part, and the measurement part measures the weight of the workpiece based on a difference in weight of the workpiece accommodation part before and after the workpiece is taken out from the workpiece accommodation part.

In the above aspect, the measurement part is provided in the workpiece support part, and the measurement part measures the weight of the workpiece supported by the workpiece support part.

In the above aspect, the workpiece support part includes a plate receiving part which receives the workpiece; and a rail part which surrounds the plate receiving part and has an upper surface supporting the workpiece at a position higher than an upper surface of the plate receiving part. As the pickup device moves relative to the workpiece support part and abuts the rail part, a support surface of the workpiece is changed from the upper surface of the rail part to the upper surface of the plate receiving part, and the measurement part measures the weight of the workpiece supported on the upper surface of the plate receiving part.

In the above aspect, the measurement part is provided in the pickup device, and the measurement part measures the weight of the workpiece held by the pickup device.

In the above aspect, a resin sealing device which resin-seals an electronic component of a workpiece including a base material and the electronic component includes: a resin sealing mold which resin-seals the electronic component by molding a resin material onto the workpiece; a workpiece accommodation part capable of accommodating at least one of the workpieces; a conveyance line for conveying the workpiece supplied from the workpiece accommodation part to the resin sealing mold; and a measurement part provided in the workpiece accommodation part and measures a weight of the workpiece.

According to this aspect, by providing the measurement part in the workpiece accommodation part, there is no need to provide a separate step for measuring the weight of the workpiece from when the workpiece is supplied to when it is conveyed to the conveyance line, and the convey time of the workpiece can be shortened. Moreover, since the weight of the workpiece is measured in the step in which the workpiece is supplied, it is possible to prepare the resin material to be supplied to the workpiece in parallel with the step in which the workpiece is conveyed to the conveyance line, the time required to resin-seal the electronic component onto the workpiece can also be shortened.

In the above aspect, further provided are a first loader which moves on the conveyance line, and conveys the workpiece to the resin sealing mold, and a second loader which conveys the resin material to the resin sealing mold.

A resin sealing method according to one aspect of the present invention resin-seals an electronic component of a workpiece including a base material and the electronic component. The resin sealing method includes: (a) a step of supplying the workpiece from a workpiece accommodation part capable of accommodating at least one of the workpieces onto a workpiece support part; (b) a step of conveying the workpiece supplied onto the workpiece support part from the workpiece accommodation part to a conveyance line using a pickup device; (c) a step of conveying the workpiece to a resin sealing mold via the conveyance line; and (d) a step of resin sealing the electronic component by molding a resin material onto the workpiece by a resin sealing mold. (a) or (b) includes a step of calculating a weight of the workpiece by a measurement part provided in at least one among the workpiece accommodation part, the workpiece support part, and the pickup device.

According to this aspect, a method for shortening the convey time of the workpiece can be provided.

### BRIEF DESCRIPTION OF DRAWINGS

FIG. 1 is a plan view of a resin sealing device according to an embodiment of the present invention.

FIG. 2A is a diagram showing an example of a cross section of a workpiece accommodation part 11 before a workpiece W is taken out from a workpiece magazine WM of a resin sealing device 1 according to the first embodiment.

FIG. 2B is a diagram showing an example of a cross section of the workpiece accommodation part 11 after the workpiece W is taken out from the workpiece magazine WM of the resin sealing device 1 according to the first embodiment.

FIG. 3 is a flowchart showing a resin sealing method in the resin sealing device according to the first embodiment.

FIG. 4A is a diagram showing an example of a cross section of a workpiece delivery part 13 before a pickup device 14 of the resin sealing device 1 according to the second embodiment acquires the workpiece W on a workpiece support part WS.

FIG. 4B is a diagram showing an example of a cross section of the workpiece delivery part 13 when the pickup device 14 of the resin sealing device 1 according to the second embodiment acquires the workpiece W on the workpiece support part WS.

FIG. 4C is a diagram showing an example of a cross section of the workpiece delivery part 13 where the pickup device 14 of the resin sealing device 1 according to the second embodiment acquires and holds the workpiece W from the workpiece support part WS.

FIG. 5A is a diagram showing an example of a cross section of the workpiece delivery part 13 before the pickup device 14 of the resin sealing device 1 according to the third embodiment acquires the workpiece W on the workpiece support part WS.

FIG. 5B is a diagram showing an example of a cross section of the workpiece delivery part 13 when the pickup device 14 of the resin sealing device 1 according to the third embodiment acquires the workpiece W on the workpiece support part WS.

FIG. 5C is a diagram showing an example of a cross section of the workpiece delivery part 13 where the pickup device 14 of the resin sealing device 1 according to the third embodiment acquires and holds the workpiece W from the workpiece support part WS.

### DESCRIPTION OF THE EMBODIMENTS

Hereinafter, an embodiment of the present invention will be described with reference to the drawings. The drawings of each embodiment are merely examples, and the dimensions and shapes of each part are schematic, and the technical scope of the present invention should not be interpreted as being limited to the embodiments.

### First Embodiment

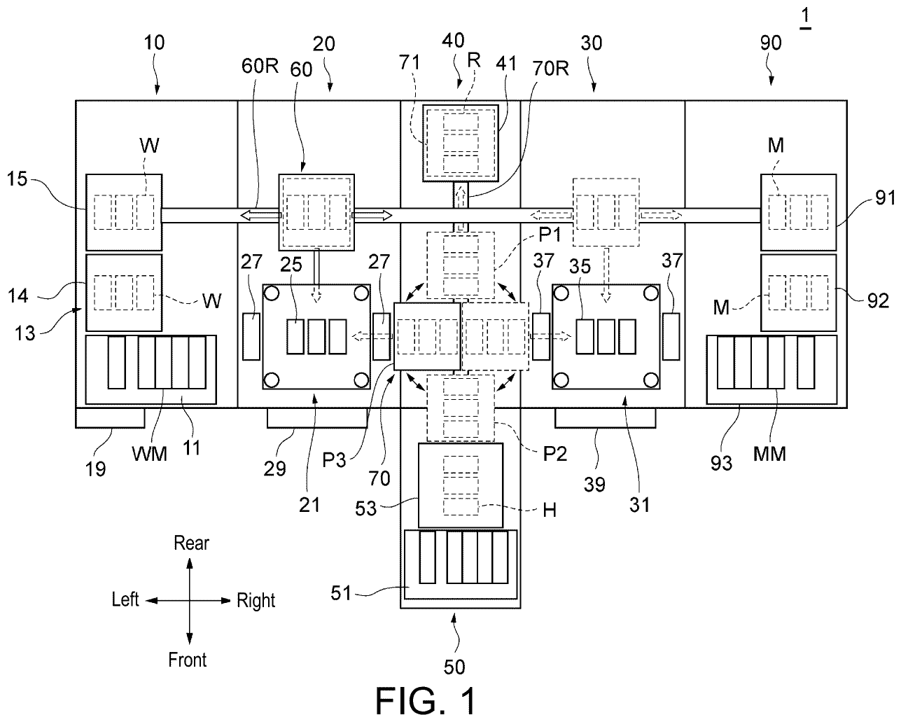

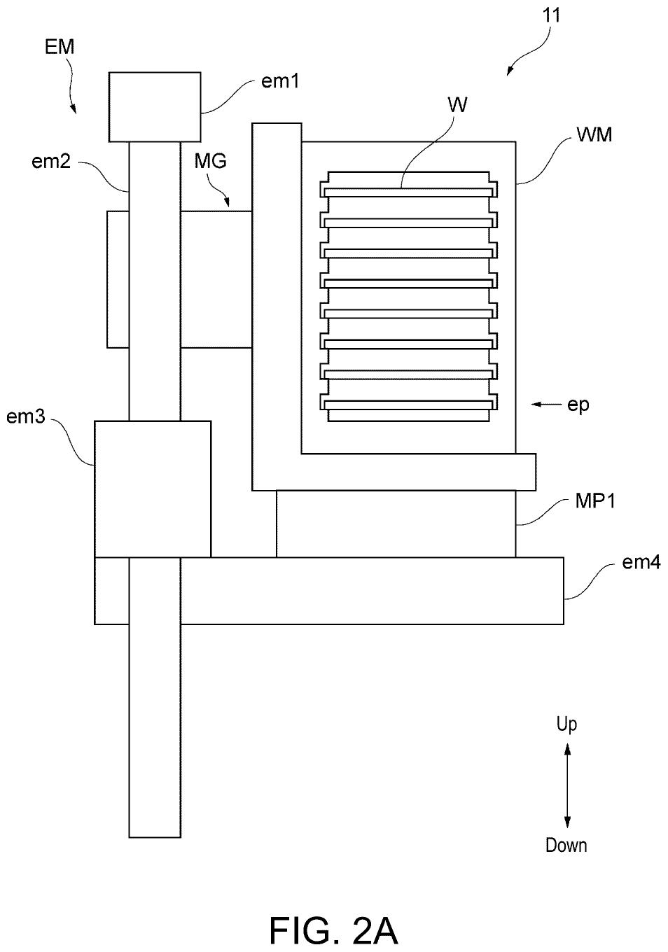

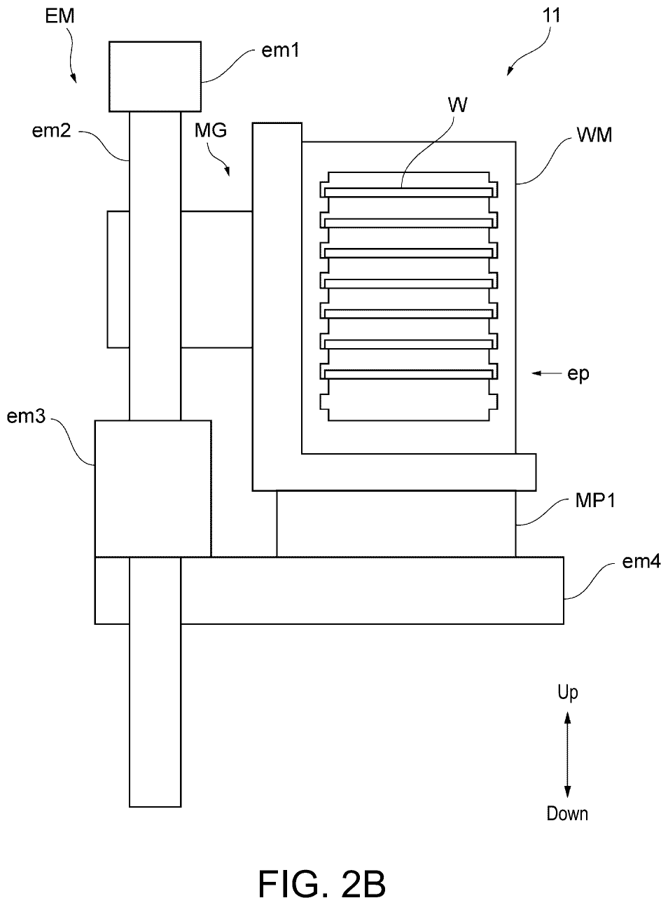

The configuration of the resin sealing device 1 according to an embodiment of the present invention will be described with reference to FIGS. 1, 2A, and 2B. FIG. 1 is a plan view of a resin sealing device according to an embodiment of the present invention. FIGS. 2A and 2B are diagrams showing an example of a configuration for measuring the weight of a workpiece W in the resin sealing device 1 according to the first embodiment. FIG. 2A is a diagram showing an example of a cross section of the workpiece accommodation part 11 before the workpiece W is taken out from the workpiece magazine WM of the resin sealing device 1 according to the first embodiment. FIG. 2B is a diagram showing an example of a cross section of the workpiece accommodation part 11 after the workpiece W is taken out from the workpiece magazine WM of the resin sealing device 1 according to the first embodiment. In the first embodiment, a measurement part MP1 is provided in the workpiece accommodation part 11. For the sake of clarity and understanding of the relative positions of the various members, each drawing is labeled with directions (front, rear, left, right, top, bottom) for the sake of convenience.

The resin sealing device 1 is a device for producing a molded product M by molding a resin material R onto a workpiece W. The workpiece W includes a base material and an electronic component. The molded product M is a workpiece W in which the electronic component are resin-sealed with the resin material R. The workpiece W corresponds to an example of a “workpiece before resin sealing”, and the molded product M corresponds to an example of a “workpiece after resin sealing”. The base material is, for example, an interposer substrate, but is not limited thereto, and may be a lead frame, a carrier plate with an adhesive sheet, a semiconductor substrate, or the like. The electronic component is, for example, a semiconductor element such as an IC chip, but is not limited thereto, and may be various active elements, passive elements, MEMS devices, or the like. The resin material R is, for example, a granular thermosetting resin, but is not limited thereto, and may be in the form of a powder, liquid, tablet, sheet, or the like. In the embodiment, as an example, the resin material R is molded onto the workpiece W and a functional member H. The functional member His, for example, a plate-shaped member. The functional member H may be, for example, a heat dissipation member that dissipates heat generated by the electronic component or a shielding member that shields electromagnetic waves. In this case, for example, the functional member H is provided so as to be exposed on the side opposite to the side on which the base material of the molded product M is exposed. Alternatively, the functional member H may be a sheet-shaped resin member.

The resin sealing device 1 according to the embodiment is a compression type resin sealing device (compression molding device). As shown in FIG. 1, the resin sealing device 1 includes a workpiece supply unit 10, a resin molding unit 20, a resin molding unit 30, a resin supply unit 40, a functional member supply unit 50, a molded product recovery unit 90, a first loader 60, and a second loader 70. The first loader 60 is movable along a first conveyance line 60R. Moreover, the second loader 70 is movable along a second conveyance line 70R.

The planar layout of the resin sealing device 1 is not particularly limited, but in the example shown in FIG. 1, the workpiece supply unit 10, the resin molding unit 20, the resin supply unit 40, the resin molding unit 30, and the molded product recovery unit 90 are disposed in this order from left to right in FIG. 1 along the first conveyance line 60R. Further, with respect to the first conveyance line 60R as a reference, a resin supply part 41 is disposed on the rear side, and the functional member supply unit 50 is disposed on the front side. The functional member supply unit 50 and the resin supply unit 40 are disposed in this order from the front to the rear in FIG. 1 along the second conveyance line 70R. Further, with respect to the second conveyance line 70R as a reference, the workpiece supply unit 10 and the resin molding unit 20 are disposed on the left side, and the resin molding unit 30 and the molded product recovery unit 90 are disposed on the right side.

The workpiece supply unit 10 supplies the workpiece W before being resin-sealed. The workpiece supply unit 10 includes the workpiece accommodation part 11, the workpiece delivery part 13, a workpiece preheat part 15, and a workpiece supply control panel 19. In the example of the planar layout shown in FIG. 1, the workpiece accommodation part 11 and the workpiece delivery part 13 are disposed in front of the first conveyance line 60R, and the workpiece delivery part 13 is disposed between the workpiece accommodation part 11 and the first conveyance line 60R in the front-rear direction. The workpiece preheat part 15 is disposed on the first conveyance line 60R. The workpiece supply control panel 19 is disposed on a front surface of the workpiece supply unit 10.

The workpiece accommodation part 11 is a supply storage part in the workpiece supply unit 10 that supplies at least one workpiece W before being resin-sealed. The workpiece accommodation part 11 stores at least one workpiece W and sends out the workpiece W. In the first embodiment, the workpiece accommodation part 11 may include the workpiece magazine WM, a magazine guide MG, the measurement part MP1, and a lifting mechanism EM.

The measurement part MP1 that is provided in the workpiece accommodation part 11 in the first embodiment measures the weight of the workpiece W based on the difference in weight of the workpiece magazine WM before and after the workpiece W is taken out from the workpiece magazine WM. In other words, from the difference between the weight of the workpiece magazine WM and the magazine guide MG before the workpiece W is taken out in FIG. 2A and the weight of the workpiece magazine WM and the magazine guide MG after the workpiece W is taken out in FIG. 2B, the measurement part MP1 calculates the weight of the taken-out workpiece W.

At least one workpiece W is accommodated in the workpiece magazine WM. As shown in FIGS. 2A and 2B, for example, the workpiece magazine WM may have slits corresponding to each of multiple workpieces W, allowing the multiple workpieces W to be accommodated such that they overlap with each other at intervals. Moreover, the workpiece magazine WM may accommodate a maximum of eight workpieces W, but the slit shape and maximum capacity of the workpiece magazine WM may be appropriately selected according to the type of the workpiece W. Moreover, the position of the workpiece magazine WM may be adjusted by the lifting and lowering operation of the lifting mechanism EM, such that the workpiece W at a take-out position ep may be taken out from among the multiple workpieces W accommodated in the workpiece magazine WM.

The magazine guide MG may hold the workpiece magazine WM such that it does not tilt. As shown in FIG. 2A and FIG. 2B, for example, the magazine guide MG may be configured to hold the workpiece magazine WM so such that it does not tilt along multiple guide rails (not shown) arranged parallel to the lifting mechanism EM to be described below, while being able to move in the up-down direction. In this case, it is smooth between the magazine guide MG and multiple guide rails (not shown) is smooth and the friction resistance is low, and the total weight of the workpiece magazine WM accommodating the multiple workpieces W and the magazine guide MG is transmitted to the measurement part MP1.

The measurement part MP1 measures the weight of the workpiece W. As shown in FIGS. 2A and 2B, for example, on the lifting mechanism EM, the measurement part MP1 may support the workpiece magazine WM via the magazine guide MG. The measurement part MP1 shown in FIG. 2A measures a total weight tw1 of the workpiece magazine WM and the magazine guide MG in which eight workpieces W are accommodated. Further, the measurement part MP1 shown in FIG. 2B measures a total weight tw2 of the workpiece magazine WM and the magazine guide MG in which seven workpieces W are accommodated. In other words, from FIG. 2A and FIG. 2B, the measurement part MP1 is able to calculate the weight of the workpiece W based on the difference in the measured total weight (total weight tw1-total weight tw2) before and after the workpiece W is taken out from the workpiece magazine WM. Moreover, in order to measure the weight of the workpiece magazine WM accommodating the workpiece W, the measurement part MP1 may perform correction based on the weight in the state where the magazine guide MG is provided on the measurement part MP1, for example.

The lifting mechanism EM adjusts the position of the workpiece magazine WM. As shown in FIG. 2A and FIG. 2B, for example, after the workpiece W at the take-out position ep is taken out from the workpiece magazine WM, the position of the workpiece magazine WM may be adjusted in accordance with the lifting and lowering operation of the lifting mechanism EM in order to place another workpiece W at the take-out position ep. The lifting mechanism EM may include: a motor em1 as a drive source, a screw shaft em2 integrally rotatably connected with the motor em1, a nut em3 screwed in such a way that it can be lifted and lowered as the screw shaft em2 rotates, and a lifting table em4 integrally connected with the nut em3 and able to be lifted and lowered. The linear motion mechanism constituted by the screw shaft em2 and the nut em3 may be, for example, a sliding screw mechanism or a ball screw mechanism.

The workpiece delivery part 13 hands over the workpiece W received from the workpiece accommodation part 11 to the first loader 60 which will be described later. For example, the workpiece delivery part 13 includes a workpiece support part WS and a pickup device 14.

The workpiece preheat part 15 preheats the workpiece W received from the workpiece delivery part 13. By preheating the workpiece W before it is conveyed to the resin molding unit 20 and the resin molding unit 30, deformation of the workpiece W due to a sudden change in temperature can be suppressed. The workpiece preheat part 15 includes a preheating heater that heats the workpiece W placed on the first loader 60. The preheating heater is, for example, a hot air heater or an infrared heater. The preheater is disposed, for example, so as to heat the workpiece W from above. The preheating heater is not limited to the above, and the workpiece W may be heated from the front-rear direction or the left-right direction. From the viewpoint of suppressing the influence of the preheater on the surrounding environment and reducing heat loss, the workpiece preheat part 15 may also include a cover that covers the periphery of the preheater. Moreover, the workpiece preheat part 15 may not need to be provided, and the workpiece W may not need to be preheated. In such case, the time until the start of carrying the resin material R and the functional member H into the resin molding unit 20 and the resin molding unit 30 or until the start of the mold closing may be controlled after the workpiece W is conveyed to the resin molding unit 20 and the resin molding unit 30.

The workpiece supply control panel 19 controls the operation of the workpiece supply unit 10. For example, the workpiece supply control panel 19 includes a display part that displays the control parameters of the workpiece supply unit 10 and an input part that inputs the control parameters of the workpiece supply unit 10. Moreover, for example, on the workpiece supply control panel 19, a display part that displays the control parameters of each of the molded product recovery unit 90, the resin supply unit 40, the functional member supply unit 50, the first loader 60 and the second loader 70 described below, and an input part that inputs the control parameters may also be integrated.

Moreover, the workpiece supply unit 10 may further include an appearance inspection part that inspects the appearance of the workpiece W.

The molded product recovery unit 90 recovers the molded product M that corresponds to the workpiece W after resin sealing. The molded product recovery unit 90 includes a molded product heat removal part 91, a molded product delivery part 92, and a molded product storage part 93. In the example of the planar layout shown in FIG. 1, the molded product delivery part 92 and the molded product storage part 93 are disposed in front of the first loader 60, and the molded product delivery part 92 is disposed between the molded product storage part 93 and the first loader 60 in the front-rear direction. The molded product heat removal part 91 is disposed so as to overlap the first loader 60.

The molded product heat removal part 91 removes heat from the molded product M to be handed over to the molded product delivery part 92. The molded product heat removal part 91 includes a heat removal cooler that cools the molded product M placed on the placement surface of a stage. The heat removal cooler is, for example, an air-cooling type cooling device or a Peltier type cooling device. The heat removal cooler is disposed, for example, so as to cool the molded product M from above. The heat removal cooler is not limited to the above, and the molded product M may be cooled from the front-rear direction or the left-right direction. Moreover, the molded product M may be cooled by natural cooling without providing the molded product heat removal part 91, or a configuration in which heat is not removed from the molded product M may be used.

The molded product delivery part 92 hands over the molded product M received from the molded product heat removal part 91 to the molded product storage part 93. For example, the molded product delivery part 92 includes a pickup device (not shown) and a feed-out part. The pickup device acquires the molded product M from the placement surface of the first loader 60, moves forward while holding the molded product M, and places the molded product M in the feed-out part. The feed-out part aligns the molded product M received from the pickup device and sends them out to the molded product storage part 93.

The molded product storage part 93 is a recovery storage part in the molded product recovery unit 90 that recovers the workpiece W after resin sealing, and corresponds to an example of a “workpiece accommodation part”. For example, the molded product storage part 93 includes a molded product magazine MM and a molded product elevation. In each of the molded product magazines, at least one molded product M is stored in an overlapping manner. The molded product elevation adjusts the position of the molded product magazine MM.

Moreover, the molded product recovery unit 90 may further include a volume measuring part that measures the volume of the molded product M, and an appearance inspection part that inspects the appearance of the molded product M.

The resin molding unit 20 molds the resin material R onto the workpiece W and the functional member H. The resin molding unit 20 includes a resin sealing mold 21, a film handler 27, and a resin molding control panel 29. In the example of the planar layout shown in FIG. 1, the resin sealing mold 21 is disposed in front of the first conveyance line 60R, and the film handler 27 is disposed on the left and right of the resin sealing mold 21. The resin molding control panel 29 is disposed on a front surface of the resin molding unit 20.

The resin sealing mold 21 includes a pair of openable and closable lower and upper molds that heat and cure the resin material R in a cavity 25 therein so as to seal the electronic component. The resin sealing mold 21 is, for example, a compression molding mold having a so-called upper cavity movable structure. Specifically, the lower mold has a flat surface on which the workpiece W is placed on a side facing the upper mold, and the upper mold has a concave surface that forms the cavity 25 on a side facing the lower mold. The resin sealing mold 21 may be a compression molding mold having a lower cavity movable structure.

The film handler 27 supplies the film to the resin sealing mold 21. The film is a release film that prevents the resin material R from entering gaps in the cavity 25 and also facilitates peeling of the molded product M from the cavity 25. The film handler 27 handles, for example, a roll-shaped film, and includes an unwinding part that supplies unused film, and a winding part that recovers used film. Moreover, as the material for the film: a polymer material having excellent heat resistance, ease of peeling, flexibility, and extensibility may be used, and examples include PTFE (polytetrafluoroethylene), ETFE (polytetrafluoroethylene-ethylene copolymer), FEP (tetrafluoroethylene-hexafluoropropylene copolymer), PET (polyethylene terephthalate), PP (polypropylene), and PVDC (polyvinylidine chloride). The thickness of the film is appropriately selected according to the physical properties of the material, and is, for example, about 50 μm. The shape of the film is not limited to a roll, but may be a strip shape.

The resin molding control panel 29 controls the operation of the resin molding unit 20. For example, the resin molding control panel 29 includes a display part that displays the control parameters of the resin molding unit 20 and an input part that inputs the control parameters of the resin molding unit 20.

The resin molding unit 30 includes a resin sealing mold 31 having a cavity 35, a film handler 37, and a resin molding control panel 39. Moreover, in the following description, details of the resin sealing mold 31, the film handler 37, and the resin molding control panel 39 are omitted, but the same configurations as those described for the resin molding unit 20 may be applied.

Moreover, at least a part of the functions of the resin molding control panel 29 and the resin molding control panel 39 may be integrated into the workpiece supply control panel 19. For example, the control parameters of the resin molding unit 20 and the resin molding unit 30 may be displayed on the display part of the workpiece supply control panel 19, and the control parameters of the resin molding unit 20 and the resin molding unit 30 may be input to the input part of the workpiece supply control panel 19. In a case where the functions of the control panels of each unit are all integrated in the workpiece supply control panel 19, the resin molding control panel 29 and the resin molding control panel 39 may be omitted.

The resin supply unit 40 supplies the resin material R. The resin supply unit 40 includes the resin supply part 41. In the example of the planar layout shown in FIG. 1, the resin supply part 41 is disposed behind the first conveyance line 60R.

The resin supply part 41 supplies the resin material R to a resin loader 71 based on the weight of the workpiece W acquired by the measurement part MP1. The resin supply part 41 includes a resin amount calculation part, and calculates the amount of the resin material R to be supplied to the resin loader 71 based on the weight of the workpiece W acquired by the measurement part MP1. The resin supply part 41 includes, for example, a hopper, a feeder, and a flow rate adjustment valve. The hopper stores the resin material R, and the feeder sends out the resin material R from the hopper to the resin loader 71. Moreover, in a case where the resin is liquid, the resin supply part 41 may also include a syringe that stores the resin, a piston that pushes out the resin, a servo motor that drives the piston, and a pinch valve that opens and closes the tip of the syringe.

Moreover, the resin supply unit 40 may further include a weight measuring part that measures the weight of the resin material R, a resin preheat part that preheats the resin material R, a resin guard used as a frame that surrounds the resin material R, a vibration part that disperses the resin material R by vibration, and an inspection part that inspects the degree of dispersion of the resin material R.

The functional member supply unit 50 supplies the functional member H. The functional member supply unit 50 includes a functional member storage part 51 and a functional member delivery part 53. In the example of the planar layout shown in FIG. 1, the functional member delivery part 53 is disposed behind the functional member storage part 51.

The functional member storage part 51 supplies the functional member to the resin loader 71. The functional member storage part 51 stores multiple functional members H and sends out the functional members H in sequence. For example, the functional member storage part 51 includes multiple functional member magazines and a functional member elevation. In each of the multiple functional member magazines, multiple functional members are accommodated in an overlapping manner. The functional member elevation adjusts the position of the multiple functional member magazines.

The functional member delivery part 53 hands over the functional member H received from the functional member storage part 51 to the resin loader 71. For example, the functional member delivery part 53 includes a functional member index part and a functional member pickup device. The functional member index part receives and aligns the functional members H sent out by the functional member storage part 51. The functional member pickup device is configured to be movable in the front-rear direction, and conveys the workpiece W between the functional member storage part 51 and the resin loader 71. The functional member pickup device acquires a functional member from the functional member index part, moves rearward while holding the functional member, and places the functional member on the resin loader 71.

Moreover, the functional member supply unit 50 may further include a volume measuring part that measures the volume of the functional member H, an appearance inspection part that inspects the appearance of the functional member H, and a functional member preheat part that preheats the functional member H. Further, the functional member supply unit 50 may be omitted, and in this case, the resin supply unit 40 may include the functions of the functional member supply unit 50 described above.

The first loader 60 conveys the workpiece W or the molded product M between the units. The first loader 60 conveys the workpiece W while moving in the left-right direction on the first conveyance line 60R as a moving path. Moreover, the first loader 60 may also include a loader hand. For example, when the first loader 60 moves to the position of the resin sealing mold 21 on the first conveyance line 60R, the loader hand conveys the workpiece W in the front-rear direction relative to the resin sealing mold 21. Specifically, the loader hand moves forward from the first loader 60 on the first conveyance line 60R while holding the workpiece W to carry the workpiece W into the resin sealing mold 21, hands over the workpiece W to the resin sealing mold 21, and moves rearward to retreat from the resin sealing mold 21. Moreover, the loader hand enters the resin sealing mold 31 from the rear, acquires the molded product M from the resin sealing mold 31, and moves rearward while holding the molded product M to convey the molded product M from the resin sealing mold 31 to the first loader 60 on the first conveyance line 60R. Moreover, the first loader 60 may move on a path different from the first conveyance line 60R. Further, the first loader 60 may be fixed at a fixed position on the first conveyance line 60R.

The second loader 70 conveys the resin material R between the resin supply unit 40 and the functional member supply unit 50. The second loader 70 and the resin loader 71 convey the resin material R while moving in the front-rear direction on the second conveyance line 70R as a moving path.

The resin loader 71 is configured to be movable between the resin supply unit 40 and the functional member supply unit 50. The resin loader 71 conveys the resin material R from the resin supply unit 40 to the resin molding unit 20 or the resin molding unit 30. Moreover, the resin loader 71 conveys the functional member H from the functional member supply unit 50 to the resin molding unit 20 or the resin molding unit 30. Although not shown in the drawings, the resin loader 71 includes a holding mechanism that holds the resin material R and the functional member H, a rotation mechanism that rotates between positions P1, P2, and P3, and an advancing/retracting mechanism that advances and retracts relative to the starting point of the rotation.

The second conveyance line 70R allows the resin loader 71 to move in the front-rear direction. The second conveyance line 70R extends in the front-rear direction across the resin supply unit 40 and the functional member supply unit 50. The second conveyance line 70R corresponds to the moving path of the resin loader 71.

In the example of the planar layout shown in FIG. 1, after receiving the resin material R at the resin supply part 41, the resin loader 71 moves to the position P1 in front of the first conveyance line 60R by the second conveyance line 70R. Next, the resin loader 71 is moved to the position P2 behind the functional member delivery part 53 by the rotation mechanism. Next, the resin loader 71 is moved to the functional member delivery part 53 by the advancing/retracting mechanism, and after receiving the functional member H, is again moved to the position P2 by the advancing/retracting mechanism. Next, the resin loader 71 is moved to the position P3 to the right of the resin sealing mold 21 by the rotation mechanism. Next, the resin loader 71 enters the resin sealing mold 21 by the advancing/retracting mechanism, and carries the resin material R and the functional member H into the resin sealing mold 21. After handing over the resin material R and the functional member H to the resin sealing mold 21, the resin loader 71 retreats from the resin sealing mold 21 by the advancing/retracting mechanism and moves again to the position P3.

For the resin sealing mold 31 of the resin molding unit 30, the second loader 70 operates in the same manner as for the resin sealing mold 21 of the resin molding unit 20. Thus, a description of the operation of the first loader 60 and the second loader 70 with respect to the resin sealing mold 31 will be omitted. However, the operation of the second loader 70 with respect to the resin sealing mold 31 is laterally reversed from the operation of the second loader 70 with respect to the resin sealing mold 21.

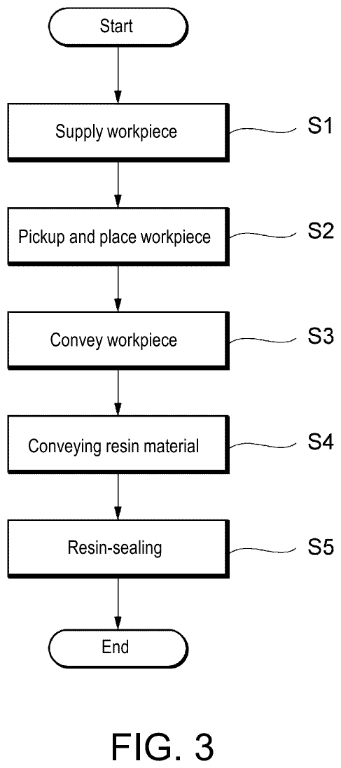

FIG. 3 is a flowchart showing a resin sealing method in the resin sealing device according to the first embodiment. As shown in FIG. 3, the resin sealing method of the first embodiment includes a step S1 of supplying a workpiece, a step S2 of picking and placing the workpiece, a step S3 of conveying the workpiece, a step S4 of conveying a resin material, and a step S5 of resin sealing. The resin sealing method of the first embodiment will be described below with reference to FIGS. 2 and 3.

### (Step S1: Supply Workpiece)

In step S1, in the workpiece accommodation part 11, the workpiece W is taken out from the workpiece magazine WM and supplied onto the workpiece support part WS of the workpiece delivery part 13. The measurement part MP1 is provided in the workpiece accommodation part 11, and the weight of the workpiece W is measured as described above.

### (Step S2: Pick and Place Workpiece)

In step S2, in the workpiece delivery part 13, the pickup device 14 acquires the workpiece W from the workpiece support part WS, moves rearward while holding the workpiece W, and places the workpiece W on the first loader 60.

### (Step S3: Convey Workpiece)

In step S3, the first loader 60 on which the workpiece W is placed moves in the left-right direction on the first conveyance line 60R, and conveys the workpiece W to the position of the resin sealing mold 21.

### (Step S4: Convey Resin Material)

In step S4, the second loader 70 receives the resin material R, moves in the front-rear direction on the second conveyance line 70R, and conveys the resin material R to the position of the resin sealing mold 21. At this time, in the resin amount calculation part of the resin supply part 41 the resin material R to be supplied to the workpiece W is calculated based on the weight of the workpiece W acquired from the measurement part MP1 in step S1, and the resin material R is supplied to the second loader 70, which conveys it to the resin sealing mold 21. Moreover, once the weight of the workpiece W is acquired in step S1, step S4 may proceed in parallel with steps S1 to S3.

(Step S5: Seal with Resin)

In step S5, in the resin sealing mold 21, the workpiece W conveyed from the first loader 60 is compression molded using the resin material R conveyed from the second loader 70 to seal the electronic component with resin.

In the above, in the resin sealing device 1 according to the first embodiment, the configuration in which the measurement part MP1 is provided in the workpiece accommodation part 11 is described. In the resin sealing device 1 according to the first embodiment, the weight of the workpiece W is measured by the measurement part MP1 that is provided in the workpiece accommodation part 11 in the step of supplying the workpiece W. As a result, in the resin amount calculation part, an appropriate resin amount of the resin material R to be supplied to each workpiece W may be calculated based on the weight information of the workpiece W previously acquired from the measurement part MP1, and the amount may be supplied to the workpiece W. Moreover, since there is no need to provide a separate step for measuring the weight of the workpiece W, it is possible to shorten the convey time from when the workpiece W is supplied from the workpiece accommodation part 11 to when it is conveyed onto the first conveyance line 60R via the workpiece delivery part 13.

Moreover, since the weight of the workpiece W is measured by the measurement part MP1 in step S1, once the weight of the workpiece W is acquired, calculation of the resin amount of the resin material R in step 4 may proceed in parallel in the resin supply part 41. As a result, in the resin sealing method from step S1 to step S5, the time required for sealing the electronic component on the workpiece W with resin can be shortened.

### Second Embodiment

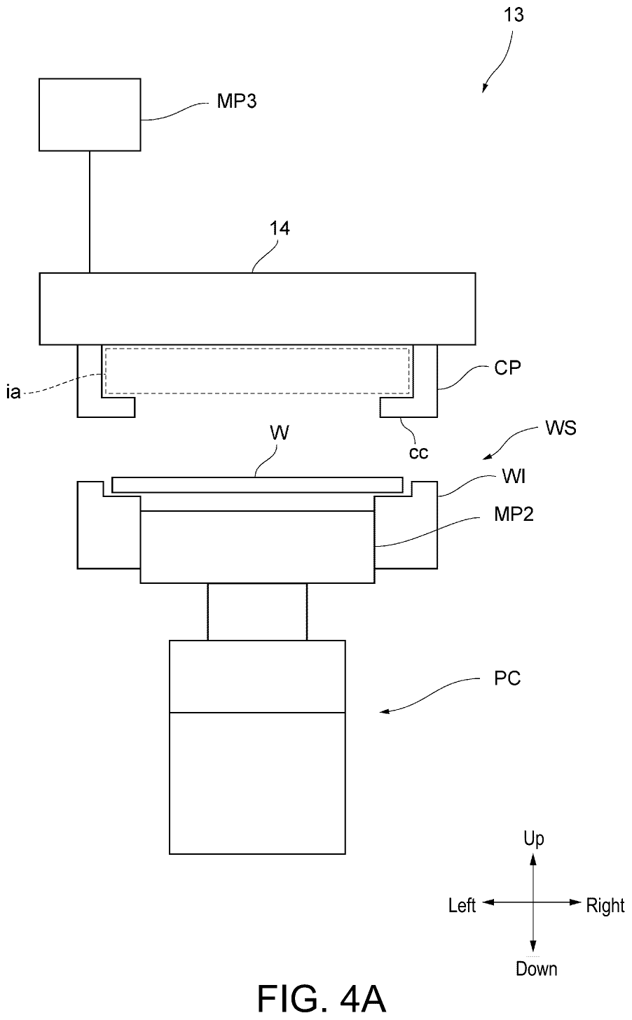

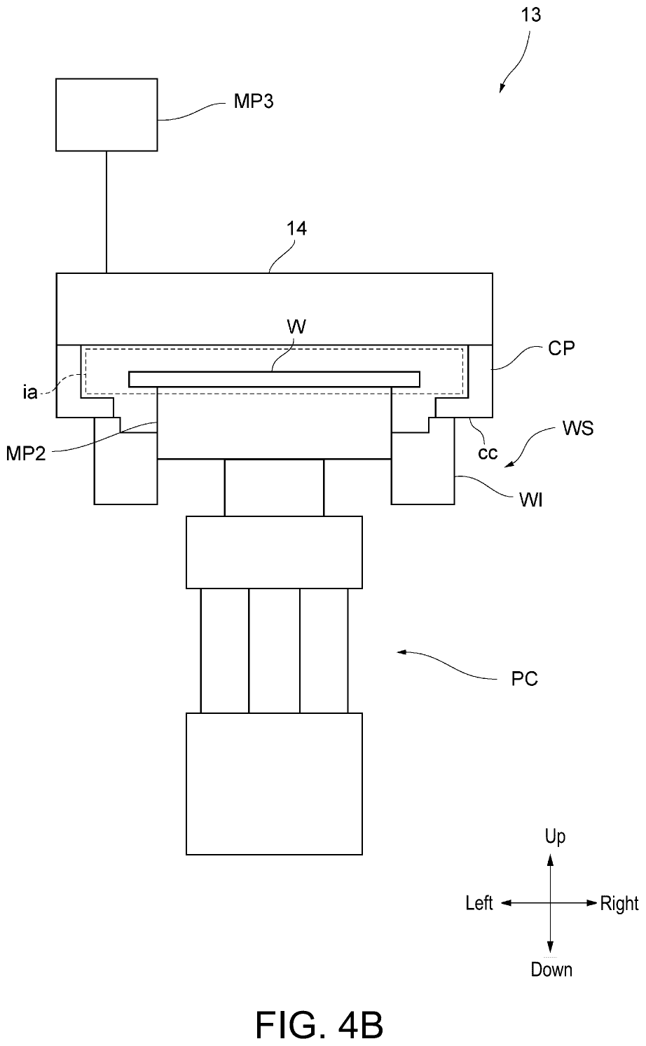

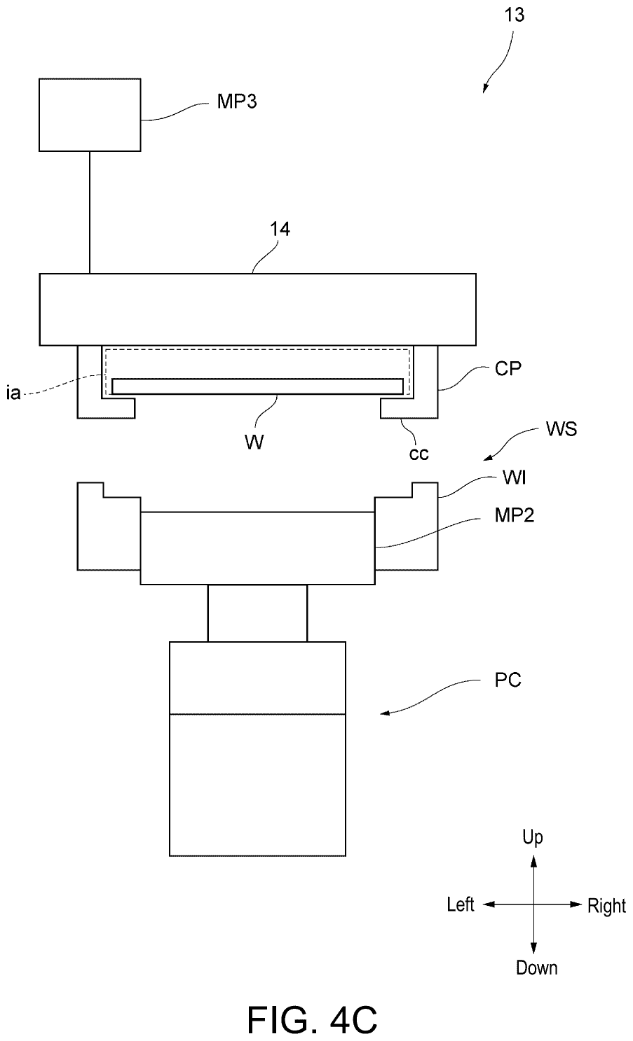

FIGS. 4A, 4B, and 4C are diagrams showing another example of the configuration for measuring the weight of the workpiece W in the resin sealing device 1 according to the second embodiment. The second embodiment will be described taking as an example a case where the weight of the workpiece W is measured in the workpiece delivery part 13 and in the step S2 shown in the first embodiment of FIG. 1 and FIG. 3. FIG. 4A is a diagram showing an example of a cross section of the workpiece delivery part 13 before the pickup device 14 of the resin sealing device 1 according to the second embodiment acquires the workpiece W on the workpiece support part WS. FIG. 4B is a diagram showing an example of a cross section of the workpiece delivery part 13 when the pickup device 14 of the resin sealing device 1 according to the second embodiment acquires the workpiece W on the workpiece support part WS. FIG. 4C is a diagram showing an example of a cross section of the workpiece delivery part 13 where the pickup device 14 of the resin sealing device 1 according to the second embodiment acquires and holds the workpiece W from the workpiece support part WS.

The workpiece support part WS may include a rail part WI that receives and aligns the workpieces W sent out by the workpiece accommodation part 11, a measurement part MP2 that measures the weight of the workpiece W, and a piston member PC that delivers the workpiece W to the pickup device 14. As shown in FIGS. 4A, 4B, and 4C, the pickup device 14 acquires the workpiece W from the workpiece support part WS. The pickup device 14 moves to the first conveyance line 60R while holding the workpiece W, and places the workpiece W on the first loader 60.

The rail part WI may align the workpieces W. As shown in FIG. 4A, for example, the rail part WI may align the workpieces W taken out from the take-out position ep of the workpiece magazine WM to a position where the they may be delivered to the pickup device 14 described later. Moreover, the workpieces W may be taken out from the workpiece magazine WM onto the rail part WI using a known pusher (not shown) and aligned along grooves on the rail part WI. Further, the rail part WI may have grooves for aligning the multiple workpieces W, and for example, the rail part WI may be rotated to align the multiple workpieces W.

The piston member PC may perform an extension and contraction operation so as to deliver the workpiece W to the pickup device 14. As shown in FIG. 4A and FIG. 4B, for example, the piston member PC is capable of extending and contracting in the up-down direction and may perform an extension and contraction operation to push up the workpieces W aligned by the rail part WI to an inner area ia where the pickup device 14 is capable of gripping the workpieces W. As shown in FIG. 4C, the piston member PC may contract and the pickup device 14 may grip the workpiece W. The extension and contraction operation of the piston member PC may be performed, for example, by air pressure, hydraulic pressure, or electromagnetic force. Moreover, as shown in FIG. 4B, as the piston member PC performs an extension and contraction operation to push up the workpiece W, the rail part WI may also be pushed up at the same time. Moreover, the rail part WI may also remain in the position shown in FIG. 4A.

The measurement part MP2 may measure the weight of the workpiece W. As shown in FIG. 4A and FIG. 4B, for example, the measurement part MP2 is attached to the tip of the piston member PC and, in an initial stop state in which the piston member PC is not in operation, is disposed to face the workpiece W with a gap therebetween, and may move upward while supporting the workpiece W when the piston member PC performs an extension and contraction operation for pushing up. The measurement part MP2 may measure the weight of the workpiece W during the extension and contraction operation of the piston member PC for pushing up, or may measure the weight of the workpiece W while the piston member PC has pushed the workpiece W up to a position where the pickup device 14 is able to grip and hold.

The pickup device 14 conveys the workpiece W to the first loader 60 on the first conveyance line 60R. As shown in FIGS. 4A, 4B, and 4C, for example, the pickup device 14 may include a chuck CP that is openable and closable in the left-right direction, and grip the workpiece W by opening and closing the chuck CP in conjunction with the extension and contraction operation of the piston member PC. In other words, the pickup device 14 may control the chuck CP in the closed state shown in FIG. 4A in conjunction with the extension and contraction operation of the piston member PC to push up the workpiece W toward the pickup device 14, such that the chuck CP shown in FIG. 4B becomes an open state. Moreover, the pickup device 14 may control the chuck CP in the open state shown in FIG. 4B in conjunction with the piston member PC pushing the workpiece W up into the inner area ia, such that the chuck CP becomes a closed state so as to grip the workpiece W. Moreover, as shown in FIG. 4B, the pickup device 14 may control the chuck CP to become a closed state so as to grip the workpiece W while chuck claws cc of the chuck CP in the open state abut against the rail part WI. Also, as shown in FIG. 4C, the piston member PC may contract and the pickup device 14 may grip the workpiece W. After the operations of FIGS. 4A to 4C, the pickup device 14 may convey the workpiece W to the first loader 60. Moreover, the pickup device 14 may move in the left-right direction to the position of the workpiece support part WS where the multiple workpieces W are received. Moreover, the workpiece support part WS may move in the left-right direction to a position where it is capable of delivering the multiple workpieces W to the pickup device 14 after receiving them.

A measurement part MP3 may measure the weight of the workpiece W. As shown in FIGS. 4A, 4B, and 4C, for example, the measurement part MP3 may be connected to the pickup device 14, and measure the weight of the workpiece W in a state where the pickup device 14 grips the workpiece W, or may measure the weight of the workpiece W while the pickup device 14 is conveying the workpiece W to the first loader 60. It is sufficient to provide at least one of the measurement part MP2 and the measurement part MP3.

### Third Embodiment

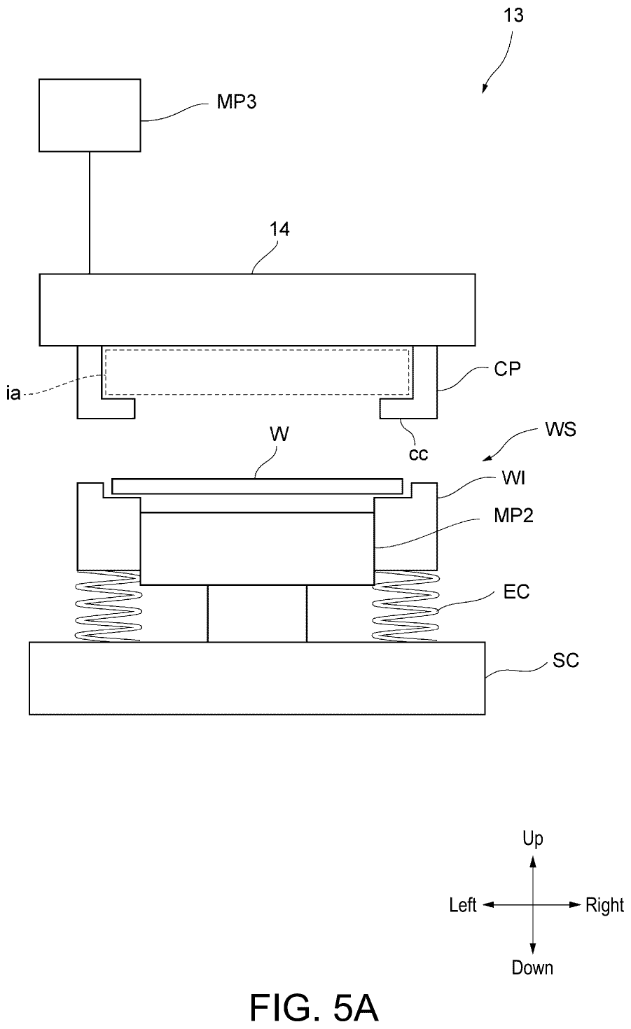

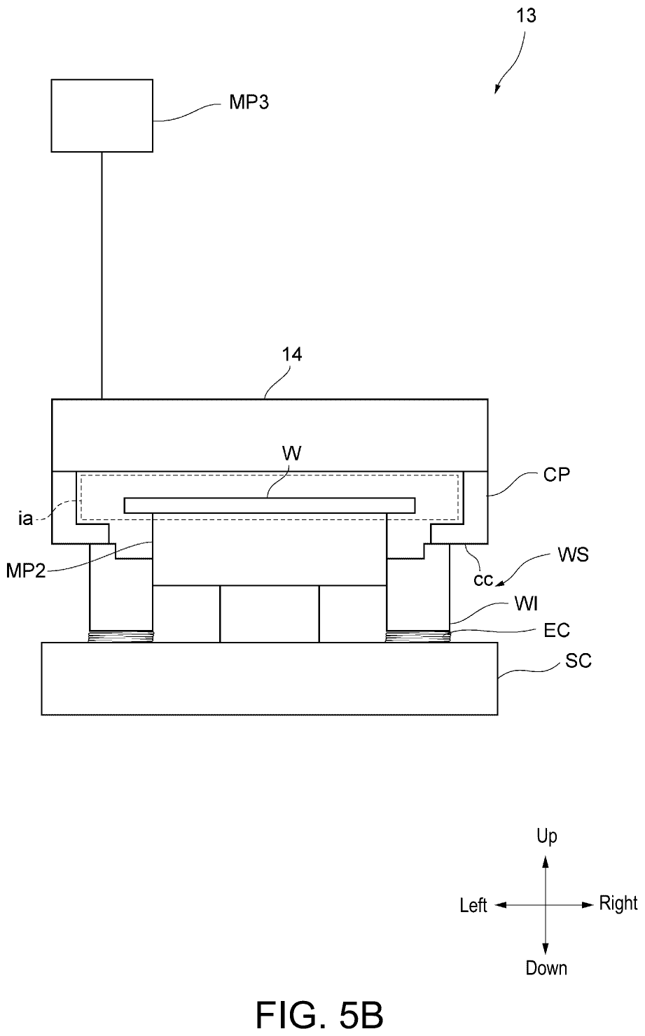

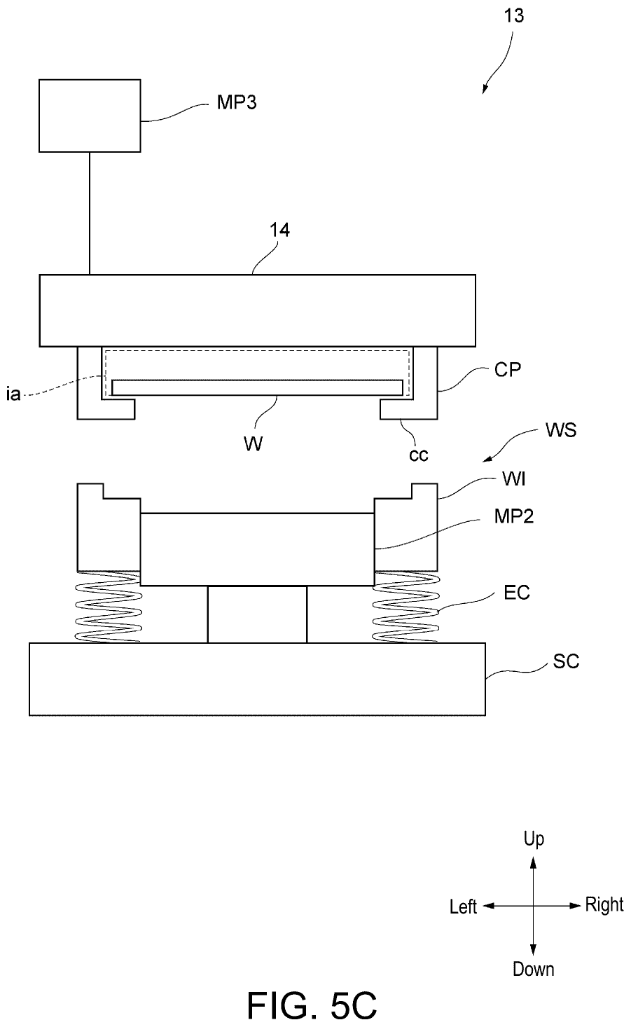

FIGS. 5A, 5B, and 5C are diagrams showing another example of the configuration for measuring the weight of the workpiece W in the resin sealing device 1 according to the third embodiment. The third embodiment will be described taking as an example a case where the weight of the workpiece W is measured in the workpiece delivery part 13 and in the step S2 shown in the first embodiment of FIG. 1 and FIG. 3. FIG. 5A is a diagram showing an example of a cross section of the workpiece delivery part 13 before the pickup device 14 of the resin sealing device 1 according to the third embodiment acquires the workpiece W on the workpiece support part WS. FIG. 5B is a diagram showing an example of a cross section of the workpiece delivery part 13 when the pickup device 14 of the resin sealing device 1 according to the third embodiment acquires the workpiece W on the workpiece support part WS. FIG. 5C is a diagram showing an example of a cross section of the workpiece delivery part 13 where the pickup device 14 of the resin sealing device 1 according to the third embodiment acquires and holds the workpiece W from the workpiece support part WS.

The workpiece support part WS may include the rail part WI that receives and aligns the workpieces W sent out by the workpiece accommodation part 11, an elastic member EC that elastically deforms the rail part WI, the measurement part MP3 that measures the weight of the workpiece W, and a base SC on which the elastic member EC and the measurement part MP3 are provided. As shown in FIGS. 5A, 5B, and 5C, the pickup device 14 acquires the workpiece W from the workpiece support part WS. The pickup device 14 moves to the first conveyance line 60R while holding the workpiece W, and places the workpiece W on the first loader 60.

The rail part WI may align the workpieces W. As shown in FIG. 5A, for example, the rail part WI is disposed on the base SC via the elastic member EC so as to be elastically deformable in the up-down direction, and may align the workpiece W taken out from the take-out position ep of the workpiece magazine WM to a position where it may be delivered to the pickup device 14 described below. Moreover, the workpieces W may be taken out from the workpiece magazine WM onto the rail part WI using a known pusher (not shown) and aligned along the grooves on the rail part WI. Further, the rail part WI may have grooves for aligning the multiple workpieces W, and for example, the rail part WI may be rotated to align the multiple workpieces W.

The measurement part MP2 measures the weight of the workpiece W. As shown in FIGS. 5A and 5B, for example, the measurement part MP2 may be provided on the base SC so as to face the workpiece W with a gap therebetween. The measurement part MP2 may measure the weight of the workpiece W by supporting the workpiece W by the chuck claws cc of the chuck CP provided on the pickup device 14 described later abutting against the rail part WI and the rail part WI elastically deforming downward.

The pickup device 14 conveys the workpiece W to the first loader 60. As shown in FIGS. 5A, 5B, and 5C, for example, the pickup device 14 may include the chuck CP that is openable and closable in the left-right direction, and grip the workpiece W by lifting and lowering the workpiece support part WS and opening and closing the chuck CP in conjunction therewith. In other words, the pickup device 14 may control the chuck CP shown in FIG. 5A in the closed state in conjunction with the operation of the pickup device 14 downward toward the workpiece support part WS, such that the chuck CP shown in FIG. 5B becomes an open state. Moreover, in a state where the chuck claws cc of the chuck CP provided on the pickup device 14 abut and elastically deform the rail part WI, the pickup device 14 may control the chuck CP in the open state shown in FIG. 5B to become a closed state so as to grip the workpiece W. Moreover, as shown in FIG. 5C, the pickup device 14 may rise and the pickup device 14 grip the workpiece W. After the operations of FIGS. 5A to 5C, the pickup device 14 may convey the workpiece W to the first loader 60. Moreover, the workpiece support part WS may move in the left-right direction to a position where it is capable of delivering the multiple workpieces W to the pickup device 14 after receiving them. Further, the pickup device 14 may move in the left-right direction to the position of the workpiece support part WS where the multiple workpieces W are received.

The measurement part MP3 may measure the weight of the workpiece W. As shown in FIGS. 5A, 5B, and 5C, for example, the measurement part MP3 is connected to the pickup device 14, and may measure the weight of the workpiece W in a state where the pickup device 14 grips the workpiece W, or may measure the weight of the workpiece W while the pickup device 14 is conveying the workpiece W to the first loader 60. Moreover, it is sufficient to provide at least one of the measurement part MP2 and the measurement part MP3.

As described above, in the resin sealing device 1 according to the first to third embodiments, an example in which the weight of the workpiece W is measured by providing the measurement part MP1 in the workpiece accommodation part 11, the measurement part MP2 in the workpiece support part WS, and the measurement part MP3 in the pickup device 14 is described. The measurement parts MP1, MP2 and MP3 only need to include at least one among the workpiece accommodation part 11, the workpiece support part WS, and the pickup device 14. In this way, by adopting a configuration of measuring the weight of the workpiece W while the workpiece W is being conveyed to the first loader 60 on the first conveyance line 60R, there is no need to provide a separate step for measuring the weight of the workpiece W, and the convey time of the workpiece W can be shortened. For example, in a case where some of the multiple chips mounted on the workpiece W are defective, there is no need to provide a separate step for accurately measuring and changing the resin amount of resin material to be supplied to the workpiece W based on the degree of defect, and it is possible to calculate the resin amount of resin material to be supplied to the workpiece W by measuring the weight of the workpiece W.

### Other Embodiments

In the above, in the resin sealing device 1 according to the first to third embodiments, a case of a compression type resin sealing device applied in the present invention is described. In the present invention, a transfer type resin sealing device may also be applied instead of the compression type resin sealing device. Even when using a transfer type resin sealing device, as with the compression type resin sealing device in FIG. 1, by adopting a configuration of measuring the weight of the workpiece W while the workpiece W is being conveyed to the first loader 60 on the first conveyance line 60R, there is no need to provide a separate step for measuring the weight of the workpiece W, and the convey time of the workpiece W can be shortened. Moreover, in a transfer type resin sealing device, resin sealing is performed regardless of the degree of defect of the workpiece W by filling a resin material into a resin sealing mold and curing it. In this case, based on the weight information of the workpiece W, it is possible to remove the workpiece W that are defective beforehand, before the resin sealing is performed.

The above-described embodiment is intended to facilitate understanding of the present invention, and is not intended to limit the present invention. The elements of the embodiments, as well as their arrangement, materials, conditions, shapes, sizes, etc. are not limited to those exemplified, and may be modified as appropriate. Further, configurations shown in different embodiments may be partially substituted or combined with each other.

### REFERENCE SIGNS LIST

1 Resin sealing device
10 Workpiece supply unit
11 Workpiece accommodation part
13 Workpiece delivery part
14 Pickup device
20, 30 Resin molding unit
21 Resin sealing mold
40 Resin supply unit
50 Functional member supply unit
60 First loader
70 Second loader
90 Molded product recovery unit
60R First conveyance line
70R Second conveyance line
W Workpiece
R Resin
H Functional member
WM Workpiece Magazine
MG Magazine Guide
ep Take-out position
MP1, MP2, MP3 Measurement part
EM Lifting mechanism
em1 Motor
em2 Screw shaft
em3 Nut
em4 Lifting table
WS Workpiece support part
WI Rail part
PC Piston member
CP Chuck
cc Chuck claw
ia Inner area
EC Elastic member
SC Base

1. A resin sealing device which resin-seals an electronic component of a workpiece comprising a base material and the electronic component, the resin sealing device comprising:
a resin sealing mold which resin-seals the electronic component by molding a resin material onto the workpiece;
a conveyance line for conveying the workpiece to the resin sealing mold;
a workpiece accommodation part capable of accommodating at least one of the workpieces;
a workpiece support part which is provided between the workpiece accommodation part and the conveyance line and supports the workpiece;
a pickup device which holds the workpiece supplied onto the workpiece support part from the workpiece accommodation part, and conveys the workpiece to the conveyance line; and
a measurement part which is provided in at least one among the workpiece accommodation part, the workpiece support part, and the pickup device, and measures a weight of the workpiece.

2. The resin sealing device according to claim 1, further comprising: a resin amount calculation part which calculates a resin amount of the resin material to be supplied to the workpiece on a workpiece basis, based on the weight of the workpiece acquired by the measurement part.

3. The resin sealing device according to claim 1,
wherein the measurement part is provided in the workpiece accommodation part, and
the measurement part measures the weight of the workpiece based on a difference in weight of the workpiece accommodation part before and after the workpiece is taken out from the workpiece accommodation part.

4. The resin sealing device according to claim 1,
wherein the measurement part is provided on the workpiece support part, and
the measurement part measures the weight of the workpiece supported by the workpiece support part.

5. The resin sealing device according to claim 4,
wherein the workpiece support part comprises:
a plate receiving part which receives the workpiece; and
a rail part which surrounds the plate receiving part and has an upper surface supporting the workpiece at a position higher than an upper surface of the plate receiving part,
wherein as the pickup device moves relative to the workpiece support part and abuts the rail part, a support surface of the workpiece is changed from the upper surface of the rail part to the upper surface of the plate receiving part, and
the measurement part measures the weight of the workpiece supported on the upper surface of the plate receiving part.

6. The resin sealing device according to claim 1,
wherein the measurement part is provided in the pickup device, and
the measurement part measures the weight of the workpiece held by the pickup device.

7. A resin sealing device which resin-seals an electronic component of a workpiece comprising a base material and the electronic component, the resin sealing device comprising:
a resin sealing mold which resin-seals the electronic component by molding a resin material onto the workpiece;
a workpiece accommodation part capable of accommodating at least one of the workpieces;
a conveyance line for conveying the workpiece supplied from the workpiece accommodation part to the resin sealing mold; and
a measurement part provided in the workpiece accommodation part and measures a weight of the workpiece.

8. The resin sealing device according to claim 1, further comprising:
a first loader which moves on the conveyance line, and conveys the workpiece to the resin sealing mold; and
a second loader which conveys the resin material to the resin sealing mold.

9. A resin sealing method which resin-seals an electronic component of a workpiece comprising a base material and the electronic component, the resin sealing method comprising:
(a) a step of supplying the workpiece from a workpiece accommodation part capable of accommodating at least one of the workpiece pieces onto a workpiece support part;
(b) a step of conveying the workpiece supplied onto the workpiece support part from the workpiece accommodation part to a conveyance line using a pickup device;
(c) a step of conveying the workpiece to a resin sealing mold via the conveyance line; and
(d) a step of resin sealing the electronic component by molding a resin material onto the workpiece by the resin sealing mold,
wherein (a) or (b) comprises a step of calculating a weight of the workpiece by a measurement part provided in at least one among the workpiece accommodation part, the workpiece support part, and the pickup device.

10. The resin sealing device according to claim 2, further comprising:
a first loader which moves on the conveyance line, and conveys the workpiece to the resin sealing mold; and
a second loader which conveys the resin material to the resin sealing mold.

11. The resin sealing device according to claim 3, further comprising:
a first loader which moves on the conveyance line, and conveys the workpiece to the resin sealing mold; and
a second loader which conveys the resin material to the resin sealing mold.

12. The resin sealing device according to claim 4, further comprising:
a first loader which moves on the conveyance line, and conveys the workpiece to the resin sealing mold; and
a second loader which conveys the resin material to the resin sealing mold.

13. The resin sealing device according to claim 5, further comprising:
a first loader which moves on the conveyance line, and conveys the workpiece to the resin sealing mold; and
a second loader which conveys the resin material to the resin sealing mold.

14. The resin sealing device according to claim 6, further comprising:
a first loader which moves on the conveyance line, and conveys the workpiece to the resin sealing mold; and
a second loader which conveys the resin material to the resin sealing mold.

15. The resin sealing device according to claim 7, further comprising:
a first loader which moves on the conveyance line, and conveys the workpiece to the resin sealing mold; and
a second loader which conveys the resin material to the resin sealing mold.
